(19) United States
(12) Patent Application Publication
(10) Pub. No.: US 2024/0202409 A1
(43) Pub. Date: Jun. 20, 2024

(54) AUTOMATIC CONVERSION METHOD AND SYSTEM OF BINDING PINS

(71) Applicant: Shenzhen China Star Optoelectronics Semiconductor Display Technology Co., Ltd., Shenzhen, Guangdong (CN)

(72) Inventors: Siyang LIU, Shenzhen, Guangdong (CN); Zui WANG, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/419,327

(22) PCT Filed: May 31, 2021
(86) PCT No.: PCT/CN2021/097473

§ 371 Date: Sep. 26, 2023

(30) Foreign Application Priority Data
Feb. 10, 2021 (CN) 202110184817.9

(51) Int. Cl. G06F 30/31

(52) U.S. Cl. CPC G06F 30/31

(57) ABSTRACT

An automatic conversion method and system of binding pins are provided. The automatic conversion method includes: defining signal identifiers of binding pins of a display panel; and recognizing the signal identifiers of the binding pins of the display panel automatically by an electronic design automation program, and generating and outputting signal identifiers of binding pins of a circuit board.

### BACKGROUND OF INVENTION

### Field of Invention

The present application relates to the display field and specifically to an automatic conversion method and system of binding pins.

### Description of Prior Art

In design processes of display panels, binding pins of in-plane wirings need to match connection pins of out-plane circuits. In prior art, the binding pins of the in-plane wirings and the connection pins of the out-plane circuits are manually created and checked. However, there are often hundreds or even thousands of binding pins of the in-plane wirings. The manner of creating and checking manually is inefficient, prone to mistake, and having high cost, which is not conducive to development of panel design. Therefore, providing an automatic conversion method and system of binding pins to solve the aforesaid technical problem is necessary.

### SUMMARY OF INVENTION

### Technical Problem

Embodiments of the present application provide an automatic conversion method and system of binding pins to solve a problem of low efficiency, prone to mistake, and high cost, because manually creating and checking the binding pins of in-plane wirings and the binding pins of out-plane circuits in current panel design processes.

### Technical Solution

One embodiment of the present application provides an automatic conversion method of binding pins, including:

The automatic conversion method of the binding pins includes:
defining signal identifiers of binding pins of a display panel; and
recognizing the signal identifiers of the binding pins of the display panel automatically by an electronic design automation program, and generating and outputting signal identifiers of binding pins of a circuit board.

Optionally, in some embodiments of the present application, the signal identifiers of the binding pins of the display panel include pin serial numbers and pin signals.

Optionally, in some embodiments of the present application, the pin serial numbers of the binding pins of the display panel are arabic numbers arranged in sequence, and the pin signals of the binding pins of the display panel are electric signals received by the binding pins of the display panel.

Optionally, in some embodiments of the present application, defining the signal identifiers of the binding pins of the display panel includes:
defining the binding pins of the display panel manually, and identifying the binding pins of the display panel by two levels of the pin serial numbers and the pin signals, wherein each of the pin serial numbers respectively corresponds to one of the pin signals.

Optionally, in some embodiments of the present application, recognizing the signal identifiers of the binding pins of the display panel automatically by the electronic design automation program and generating and outputting the signal identifiers of the binding pins of the circuit board include:
recognizing the signal identifiers of the binding pins of the display panel automatically by the electronic design automation program;
generating signal identifiers of first binding pins of a chip on film according to the signal identifiers of the binding pins of the display panel;
generating the signal identifiers of the binding pins of the circuit board according to the signal identifiers of the first binding pins of the chip on film; and
outputting the signal identifiers of the binding pins of the circuit board.

Optionally, in some embodiments of the present application, the first binding pins of the chip on film are pins bound to the binding pins of the display panel, and the first binding pins of the chip on film correspond to the binding pins of the display panel one-to-one.

Optionally, in some embodiments of the present application, generating the signal identifiers of the binding pins of the circuit board according to the signal identifiers of the first binding pins of the chip on film includes:
merging the signal identifiers of the first binding pins of the chip on film which are adjacent and have same pin signals automatically through the electronic design automation program, and redefining the merged signal identifiers to obtain the signal identifiers of the binding pins of the circuit board sequentially.

Optionally, in some embodiments of the present application, the binding pins of the circuit board are pins bound to second binding pins of the chip on film, the binding pins of the circuit board correspond to the second binding pins of the chip on film one-to-one, and the second binding pins of the chip on film are pins that realizes electrical signal conduction of an interior of the chip on film and the first binding pins of the chip on film.

Optionally, in some embodiments of the present application, generating the signal identifiers of the binding pins of the circuit board according to the signal identifiers of the first binding pins of the chip on film includes:
merging the signal identifiers of the first binding pins of the chip on film which are adjacent and have same pin signals automatically through the electronic design automation program, and redefining the merged signal identifiers to obtain signal identifiers of second binding pins of the chip on film sequentially; and
generating the signal identifiers of the binding pins of the circuit board according to the signal identifiers of the second binding pins of the chip on film.

Correspondingly, one embodiment of the present application further provides an automatic conversion system of the binding pins, includes
a defining module configured to define signal identifiers of binding pins of a display panel; and
a recognition module configured to recognize the signal identifiers of the binding pins of the display panel automatically;
a conversion module configured to convert the signal identifiers of the binding pins of the display panel into signal identifiers of binding pins of a circuit board; and
an output module configured to output the signal identifiers of the binding pins of the circuit board.

### Advantageous Effect

The embodiments of the present application adopt the automatic conversion method and system of the binding pins. The automatic conversion method of the binding pins includes: defining the signal identifiers of the binding pins of the display panel; and recognizing the signal identifiers of the binding pins of the display panel automatically by the electronic design automation program, and generating and outputting the signal identifiers of binding pins of the circuit board. In the present application, the signal identifiers of the binding pins of the display panel are automatically converted into the signal identifiers of the binding pins of the circuit board through the electronic design automation program, which replaces the manual creation and inspection aiming at the in-plane binding pins and the out-plane circuit binding pins, thereby improving work efficiency, reducing human error rate, and reducing labor costs.

### DESCRIPTION OF DRAWINGS

To more clearly illustrate the technical solutions of the embodiments of the present application, the accompanying figures of the present application will be described in brief. Obviously, the accompanying figures described below are only part of the embodiments of the present application, from which figures those skilled in the art can derive further figures without making any inventive efforts.

FIG. 1 is a first flowchart of an automatic conversion method of binding pins provided by one embodiment of the present application.

FIG. 2 is a second flowchart of the automatic conversion method of the binding pins provided by one embodiment of the present application.

FIG. 3 is a first conversion schematic diagram of the automatic conversion method of the binding pins provided by one embodiment of the present application.

FIG. 4 is a second conversion schematic diagram of the automatic conversion method of the binding pins provided by one embodiment of the present application.

FIG. 5 is a third conversion schematic diagram of the automatic conversion method of the binding pins provided by one embodiment of the present application.

FIG. 6 is a first block diagram of an automatic conversion system of the binding pins provided by one embodiment of the present application.

FIG. 7 is a second block diagram of the automatic conversion system of the binding pins provided by one embodiment of the present application.

FIG. 8 is a third block diagram of the automatic conversion system of the binding pins provided by one embodiment of the present application.

### DETAILED DESCRIPTION OF EMBODIMENTS

The technical solutions in the embodiments of the present application are clearly and completely described in the following with reference to the accompanying drawings in the embodiments of the present application. Obviously, the described embodiments are only part of the embodiments of the present application, and are not all embodiments of the present application. All other embodiments obtained by those skilled in the art based on the embodiments of the present application without creative efforts are within the scope of the present application. Besides, it should be understood that the specific embodiments described herein are merely for describing and explaining the present application and are not intended to limit the present application. In the present application, unless opposite stated, the orientation words used such as “upper” and “lower” generally refer to the upper and lower directions of the device in actual using or working state, and specifically refer to the drawing directions in the drawings, and “inner” and “outer” refer to the outline of the device.

Embodiments of the present application provide an automatic conversion method and system of binding pins. The details are described below respectively. It should be noted that a description order of the following embodiments is not intended to limit a preferred order of the embodiments.

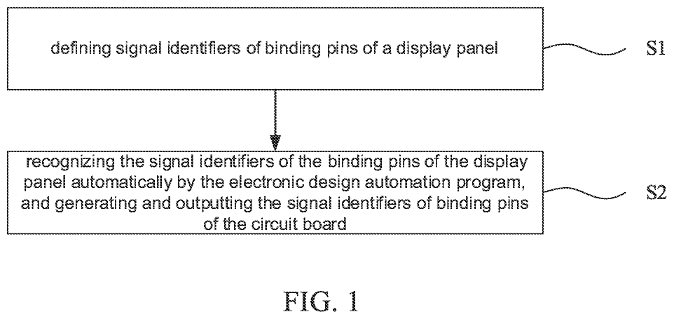

In one embodiment, please refer to FIG. 1. In FIG. 1, a first flowchart of an automatic conversion method of binding pins provided by one embodiment of the present application is illustrated. The automatic conversion method of the binding pins provided by one embodiment of the present application provides includes:
S1: defining signal identifiers of binding pins of a display panel.

Specifically, definitions of each binding pin of the display panel is manually designated by a user to assign the signal identifiers of each binding pin of the display panel, and the signal identifiers include pin serial numbers and pin signals. Optionally, Arabic numbers are adopted as the pin serial numbers, and first-level identifiers of the binding pins of the display panel are carried out by Arabic numbers arranged in sequence. Meanwhile, electrical signals received by the binding pins are adopted as pin signals. Because each binding pin of the display panel is connected to at least one in-plane signal line of the display panel correspondingly, the second-level identifiers of the binding pins of the display panel is carried out by electrical signals transmitted by the in-plane signal lines of the display panel connected to the binding pins of the display panel.

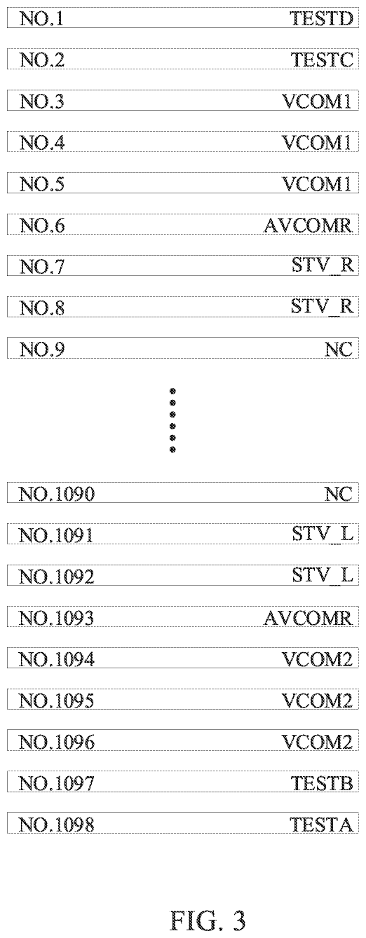

Please refer to FIG. 3. FIG. 3 is a first conversion schematic diagram of the automatic conversion method of the binding pins provided by one embodiment of the present application, which specifically illustrates the signal identifiers of the binding pins of one display panel. As illustrated in FIG. 3, there are 1098 binding pins in the display panel. The binding pins of the display panel are labeled and ordered with Arabic numbers 1, 2, 3 . . . 1096, 1097, and 1098 from left to right in sequence. The Arabic numbers corresponding to the binding pins are the pin serial numbers of the binding pins. Meanwhile, electrical signals TESTD, TESTC, VCOM1 . . . VCOM2, TESTB and TESTA connected to the binding pins are adopted on each binding pin to carry out identifiers of pin signal levels. As illustrated in the figures, the electrical signal received by the binding pin with the pin serial number 1 is TESTD, the pin signal of the binding pin is TESTD, and the signal identifier of the binding pin is pin serial number of 1 and the pin signal of TESTD; and the electrical signal received by the binding pin with the pin serial number 6 is AVCOMR, the pin signal of the binding pin is AVCOMR, and the signal identifier of the binding pin is pin serial number of 6 and the pin signal of AVCOMR. Each binding pin of the display panel has one pin serial number and one pin signal. Furthermore, each pin serial number corresponds to one pin signal respectively, and one pin signal can correspond to one or the plurality of pin serial numbers. When one pin signal correspond to the plurality of pin serial numbers at a same time, these pin serial numbers can be adjacent or can be not adjacent to each other.
S2: recognizing the signal identifiers of the binding pins of the display panel automatically by the electronic design automation program, and generating and outputting the signal identifiers of binding pins of the circuit board.

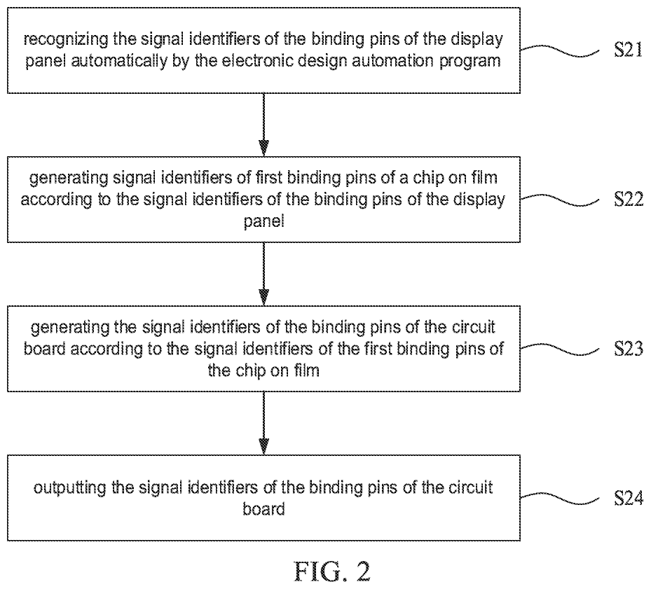

In one embodiment, please refer to FIG. 2. In FIG. 2, a second flowchart of the automatic conversion method of binding pins provided by one embodiment of the present application is illustrated. As illustrated in FIG. 2, recognizing the signal identifiers of the binding pins of the display panel automatically by the electronic design automation program and generating and outputting the signal identifiers of the binding pins of the circuit board includes:
S21: recognizing the signal identifiers of the binding pins of the display panel automatically by the electronic design automation program.

Specifically, after the signal identifiers of the binding pins of the display panel are defined, the electronic design automation (EDA) program can automatically recognize the signal identifiers of the binding pins of the display panel and can read the signal identifiers of the binding pins of the display panel, which includes the pin serial numbers and the pin signals of the binding pins of the display panel.

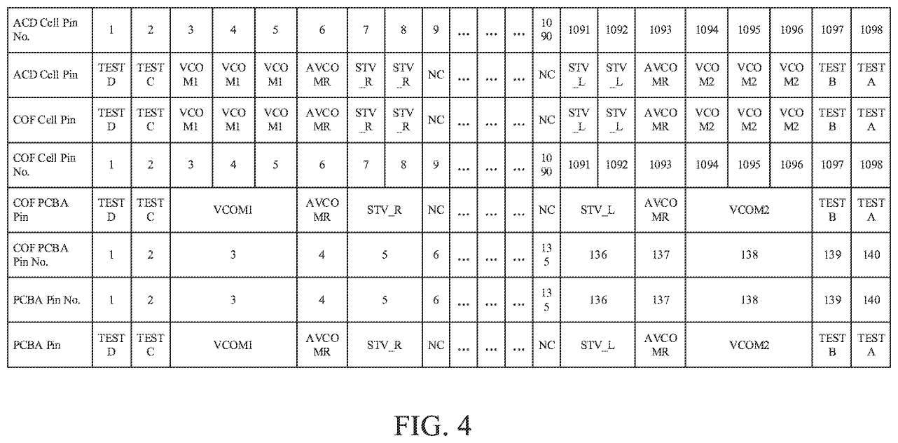

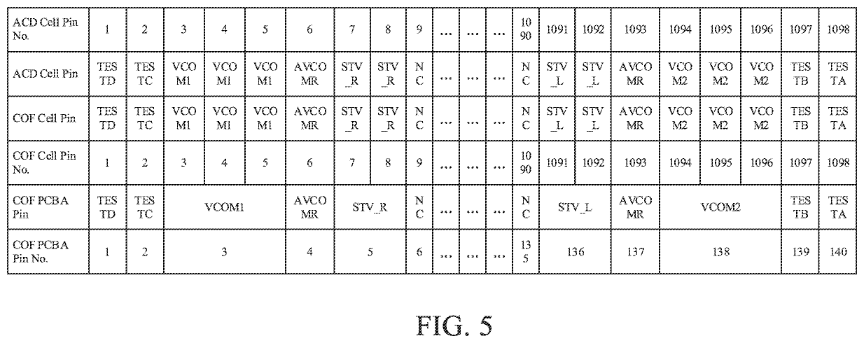

Please refer to FIG. 4. A second conversion schematic diagram of the automatic conversion method of the binding pins provided by one embodiment of the present application is illustrated in FIG. 4, and a schematic diagram of a table that the signal identifiers of the binding pins of the display panel are converted into the signal identifiers of the binding pins of the circuit board is specifically illustrated. FIG. 4 corresponds to FIG. 3. After the electronic design automation program automatically reads the signal identifiers of the binding pins of the display panel, a signal identifier table corresponding to the pin serial numbers and the pin signals of the binding pins (array color-filter design (ACD) cell pins) of the display panel as illustrated in the first two rows in FIG. 4 or FIG. 5 is obtained.
S22: generating signal identifiers of first binding pins of a chip on film according to the signal identifiers of the binding pins of the display panel.

In a design of the display panel, a first binding pins of a chip on film are pins bound to the binding pins of the display panel, and the first binding pins of the chip on film correspond to the binding pins of the display panel one-to-one. As the first binding pins of the chip on film one-to-one correspond to and are in bind connection with the binding pins of the display panel, a number of the first binding pins of the chip on film is same as a number of the binding pins of the display panel, pin serial numbers of the first binding pins of the chip on film and the pin serial numbers of the binding pins of the display panel correspond to each other one to one and are same, pin signals of the first binding pins of the chip on film and the pin signals of the binding pins of the display panel correspond to each other one to one and are same, the pin serial numbers and the binding pins of the first binding pins of the chip on film correspond to each other one-to-one and match with each other, and a matching result is same as a matching result of the pin serial numbers and the pin signals of the binding pins of the display panel.

Illustrated in a third row and a fourth row in FIG. 4 or a third row and a fourth row in FIG. 5 is a signal identifier table corresponding to obtained pin serial numbers and pin signals of the first binding pins of the chip on film (chip-on-film (COF) cell pins). The chip on film also has 1098 first binding pins. The first binding pins of the chip on film (COF cell pins) are labeled and ordered by Arabic numbers of 1, 2, 3, . . . 1096, 1097 and 1098 from left to right in sequence. The Arabic numbers corresponding to the first binding pins are the pin serial numbers of the first binding pins. Meanwhile, the pin signal of the first binding pin (COF cell pin) with the pin number of 1 is same as the pin signal of the binding pin (ACD cell pin) of the display panel with the pin number of 1, which are TESTD; the pin signal of the first binding pins (COF cell pin) with the pin number of 2 is same as the pin signal of the binding pin (ACD cell pin) of the display panel with the pin number of 2, which are TESTC; and the pin signal of the first binding pins (COF cell pin) with the pin number of 3 is same as the pin signal of the binding pin (ACD cell pin) of the display panel with the pin number of 3, which is VCOM1, as so on.
S23: generating the signal identifiers of the binding pins of the circuit board according to the signal identifiers of the first binding pins of the chip on film.

Specifically, the signal identifiers of the first binding pins of the adjacent chips on film with same pin signals are merged by the electronic design automation program, and the signal identifiers after merged are redefined in sequence to obtain the signal identifiers of second binding pins of the chip on film. Signal identifiers of the second binding pins of the chip on film include redefined pin serial numbers and pin signals. Similarly, each second pin signal has one pin serial number and one pin signal. One pin serial number corresponds to one pin signal, and one pin signal can correspond to one or a plurality of pin serial numbers. When one pin signal correspond to the plurality of pin serial numbers at a same time, these pin serial numbers are not adjacent to each other.

The pin signal of the first binding pin with the pin serial number of 1 is different from the pin signal of the first binding pin with pin serial number of 2, so the signal identifier with the pin number of 1 and the signal identifiers TESTD is preserved to act as the signal identifier of the second binding pin with the pin number of 1 and the signal identifiers TESTD; the pin signal of the first binding pin with the pin serial number of 2 is different from the pin signal of the first binding pin with pin serial number of 3, so the pin number is 2 and the signal identifiers of the pin signal is TESTC is preserved to act as the signal identifier of the second binding pin with the pin number of 2 and the signal identifiers TESTC; pin signals of the first binding pins with pin serial numbers of 3, 4, and 5 are VCOM1, The signal identifiers of the first binding pins with adjacent pin serial numbers of 3, 4, and 5 are merged, the merged signal identifiers act as the signal identifier of the second binding pin with the pin serial number of 3 and the pin signal of VCOM1; the pin signal of the first binding pin with the pin serial number of 6 is different from the pin signal of the first binding pin with pin serial number of 7, so it is redefined as the signal identifier of the second binding pin with the pin serial number of 4 and the pin signal of AVCOMR in sequence; as so on, the signal identifier table corresponding to the pin serial numbers and the pin signals of the second binding pins of the chip on film (COF printed circuit board assembly (PCBA) pin) illustrated in a fifth row and sixth row in FIG. 4 or a fifth row and sixth row in FIG. 5 is obtained.

In addition, in the design of the display panel, because the second binding pins of the chip on film are the pins bound to the binding pins of the circuit board, the second binding pins of the chip on film correspond to the binding pins of the circuit board one-to-one. The second binding pins of the chip on film one-to-one correspond to and are in bind connection with the binding pins of the circuit board, so a number of the second binding pins of the chip on film is same as the number of the binding pins of the circuit board. Pin serial numbers of the second binding pins of the chip on film and the pin serial numbers of the binding pins of the circuit board correspond to each other one to one and are same. Pin signals of the second binding pins of the chip on film and the pin signals of the binding pins of the circuit board correspond to each other one to one and are same. The pin serial numbers and the binding pins of the binding pins of the circuit board correspond to each other one-to-one and match with each other, and a matching result is same as a matching result of the pin serial numbers and the pin signals of the second binding pins of the chip on film. That is, the signal identifiers of the binding pins of the circuit board are completely same as the signal identifiers of the second binding pins of the chip on film. In one embodiment, after the signal identifiers of the first binding pins of the chip on film is converted into the signal identifiers of the second binding pins of the chip on film, as illustrated in a seventh tow and an eighth row of FIG. 4, the signal identifier table of the binding pins (PCBA pins) of the circuit board are generated by the signal identifiers of the second binding pins of the chip on film. In another embodiment, when the signal identifiers of the first binding pins of the chip on film are converted into the signal identifiers of the second binding pins of the chip on film, the signal identifier table of the second binding pins of the chip on film is regarded as an obtained signal identifier table of the binding pins of the circuit board. Compared to the previous embodiment, as illustrated in FIG. 5, there is no need to generate the signal identifier table of the binding pins of the circuit board according to the signal identifiers of the second binding pins of the chip on film.

In order to recognize easily, the adjacent tables belonging to same pin signals in the signal identifier tables can be filled with a same color, and the adjacent tables belonging to different pin signals can be filled with different colors.
S24: outputting the signal identifiers of the binding pins of the circuit board.

In the automatic conversion method of the binding pins provided by the embodiments of the present application, the signal identifiers of the binding pins of the display panel are automatically converted into the signal identifiers of the binding pins of the circuit board through the electronic design automation program, which replaces the operation of the in-plane binding pins and the out-plane circuit binding pins created and checked manually, thereby improving work efficiency, reducing human error rate, and reducing labor costs.

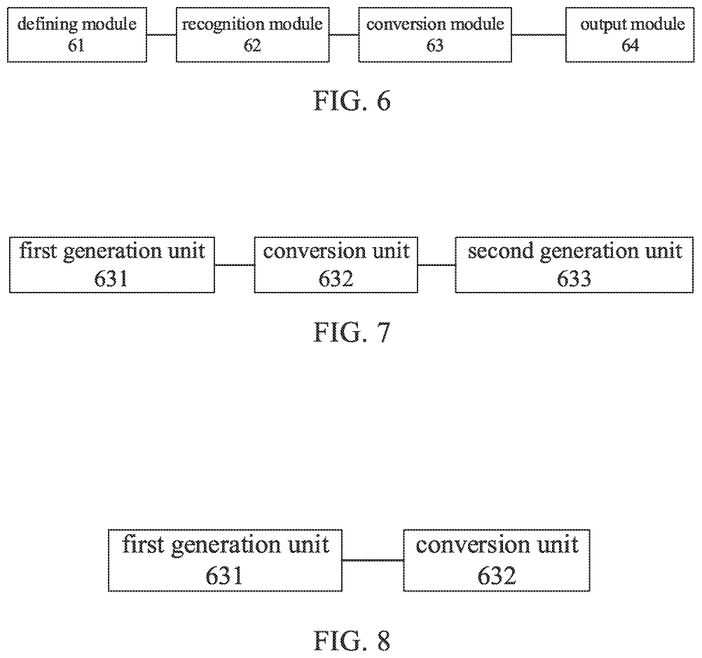

Correspondingly, one embodiment of the present application further provides an automatic conversion system of the binding pins, which is configured to carry out the automatic conversion method of the binding pins provided by the present application. Please refer to FIG. 6. A first block diagram of an automatic conversion system of the binding pins provided by one embodiment of the present application is illustrated in FIG. 6. As illustrated in FIG. 6, the automatic conversion system of the binding pins includes:

A defining module 61, which is configured to define signal identifiers of binding pins of a display panel.

Specifically, definitions of each binding pin of the display panel is manually designated by a user to assign the signal identifiers of each binding pin of the display panel through the defining module 61, and the signal identifiers include pin serial numbers and pin signals. Optionally, Arabic numbers are adopted as the pin serial numbers, and first-level identifiers of the binding pins of the display panel are carried out by Arabic numbers arranged in sequence. Meanwhile, electrical signals received by the binding pins are adopted as pin signals, the second-level identifiers of the binding pins of the display panel is carried out by the electrical signals.

A recognition module 62, which is configured to recognize the signal identifiers of the binding pins of the display panel automatically.

Specifically, the recognition module 62 automatically recognizes the signal identifiers of the binding pins of the display panel and reads the signal identifiers of the binding pins of the display panel, which includes the pin serial numbers and the pin signals of the binding pins of the display panel.

A conversion module 63, which is configured to convert the signal identifiers of the binding pins of the display panel into signal identifiers of binding pins of a circuit board.

Specifically, the conversion module 63 obtains the pin serial numbers and the pin signals of the binding pins of the display panel read by the recognition module 62 and converts then into the signal identifiers corresponding to the pin serial numbers and the pin signals of the binding pins of the circuit board.

An output module 64, which is configured to output the signal identifiers of the binding pins of the circuit board.

In one embodiment, please refer to FIG. 7. A second block diagram of the automatic conversion system of the binding pins provided by one embodiment of the present application is illustrated in FIG. 7. As illustrated in FIG. 7, the conversion module 63 includes:
a first generation unit 631, which is configured to generate signal identifiers of the first binding pins of the chip on film according to the signal identifiers of the binding pins of the display panel.

Specifically, the first generation unit 631 obtains the pin serial numbers and the pin signals of the binding pins of the display panel read by the recognition module 62 and generates the signal identifiers of the first binding pins of the chip on film. Pin serial numbers of the first binding pins of the chip on film and the pin serial numbers of the binding pins of the display panel correspond to each other one to one and are same. Pin signals of the first binding pins of the chip on film and the pin signals of the binding pins of the display panel correspond to each other one to one and are same. The pin serial numbers and the binding pins of the first binding pins of the chip on film correspond to each other one-to-one and match with each other, and a matching result is same as a matching result of the pin serial numbers and the pin signals of the binding pins of the display panel.

A conversion unit 632, which is configured to convert the signal identifiers of the first binding pins of the chip on film into the signal identifiers of the second binding pins of the chip on film.

Specifically, the conversion unit 632 obtains the signal identifiers of the first binding pins of the chip on film in the first generation unit 631, automatically merges the signal identifiers of the first binding pins of the adjacent chips on film with same pin signals, and redefines the signal identifiers after merged in sequence to obtain the signal identifiers of second binding pins of the chip on film. Signal identifiers of the second binding pins of the chip on film include redefined pin serial numbers and pin signals. Similarly, each second pin signal has one pin serial number and one pin signal. One pin serial number corresponds to one pin signal, and one pin signal can correspond to one or a plurality of pin serial numbers. When one pin signal correspond to the plurality of pin serial numbers at a same time, these pin serial numbers are not adjacent to each other.

A second generation unit 633, which is configured to generate the signal identifiers of the binding pins of the circuit board according to the signal identifiers of the second binding pins of the chip on film.

The second binding pins of the chip on film are the pins bound to the binding pins of the circuit board, and the second binding pins of the chip on film correspond to the binding pins of the circuit board one-to-one. The second binding pins of the chip on film one-to-one correspond to and are in bind connection with the binding pins of the circuit board, so a number of the second binding pins of the chip on film is same as the number of the binding pins of the circuit board. Pin serial numbers of the second binding pins of the chip on film and the pin serial numbers of the binding pins of the circuit board correspond to each other one to one and are same. Pin signals of the second binding pins of the chip on film and the pin signals of the binding pins of the circuit board correspond to each other one to one and are same. The pin serial numbers and the binding pins of the binding pins of the circuit board correspond to each other one-to-one and match with each other, and a matching result is same as a matching result of the pin serial numbers and the pin signals of the second binding pins of the chip on film.

In another embodiment, please refer to FIG. 8. A third block diagram of the automatic conversion system of the binding pins provided by one embodiment of the present application is illustrated in FIG. 8. As illustrated in FIG. 8, the conversion module 63 includes:
the first generation unit 631 configured to generate signal identifiers of the first binding pins of the chip on film according to the signal identifiers of the binding pins of the display panel; and
the conversion unit 632 configured to convert the signal identifiers of the first binding pins of the chip on film into the signal identifiers of the second binding pins of the chip on film.

Wherein, because the signal identifiers of the binding pins of the circuit board are completely same as the signal identifiers of the second binding pins of the chip on film, the signal identifiers of the second binding pins of the chip on film converted from the signal identifiers of the first binding pins of the chip on film are regarded as the signal identifiers of the binding pins of the circuit board converted from the signal identifiers of the first binding pins of the chip on film.

The automatic conversion method and the system of the binding pins provided by the present application are described in detail above. This article uses specific cases for describing the principles and the embodiments of the present application, and the description of the embodiments mentioned above is only for helping to understand the method and the core idea of the present application. Meanwhile, for those skilled in the art, will have various changes in specific embodiments and application scopes according to the idea of the present application. In summary, the content of the specification should not be understood as limit to the present application.

What is claimed is:

1. An automatic conversion method of binding pins, comprising:
defining signal identifiers of binding pins of a display panel; and
recognizing the signal identifiers of the binding pins of the display panel automatically by an electronic design automation program, and generating and outputting signal identifiers of binding pins of a circuit board,
wherein the signal identifiers comprise first signal identifiers and second signal identifiers, and one of the second signal identifiers corresponds to a plurality of first signal identifiers.

2. The automatic conversion method of the binding pins as claimed in claim 1, wherein
the signal identifiers of the binding pins of the display panel comprise pin serial numbers and pin signals, the first signal identifiers are the pin serial numbers, and the second signal identifiers are the pin signals.

3. The automatic conversion method of the binding pins as claimed in claim 2, wherein the pin serial numbers of the binding pins of the display panel are Arabic numbers arranged in sequence, and the pin signals of the binding pins of the display panel are electric signals received by the binding pins of the display panel.

4. The automatic conversion method of the binding pins as claimed in claim 2, wherein defining the signal identifiers of the binding pins of the display panel comprises:
defining the binding pins of the display panel manually, and identifying the binding pins of the display panel by two levels of the pin serial numbers and the pin signals,
wherein each of the pin serial numbers respectively corresponds to one of the pin signals.

5. The automatic conversion method of the binding pins as claimed in claim 1, wherein recognizing the signal identifiers of the binding pins of the display panel automatically by the electronic design automation program and generating and outputting the signal identifiers of the binding pins of the circuit board comprise:
recognizing the signal identifiers of the binding pins of the display panel automatically by the electronic design automation program;
generating signal identifiers of first binding pins of a chip on film according to the signal identifiers of the binding pins of the display panel;
generating the signal identifiers of the binding pins of the circuit board according to the signal identifiers of the first binding pins of the chip on film; and
outputting the signal identifiers of the binding pins of the circuit board.

6. The automatic conversion method of the binding pins as claimed in claim 5, wherein the first binding pins of the chip on film are pins bound to the binding pins of the display panel, and the first binding pins of the chip on film correspond to the binding pins of the display panel one-to-one.

7. The automatic conversion method of the binding pins as claimed in claim 5, wherein generating the signal identifiers of the binding pins of the circuit board according to the signal identifiers of the first binding pins of the chip on film comprises:
merging the signal identifiers of the first binding pins of the chip on film which are adjacent and have same pin signals automatically through the electronic design automation program, and
redefining the merged signal identifiers to obtain the signal identifiers of the binding pins of the circuit board sequentially.

8. The automatic conversion method of the binding pins as claimed in claim 7, wherein the binding pins of the circuit board are pins bound to second binding pins of the chip on film, the binding pins of the circuit board correspond to the second binding pins of the chip on film one-to-one, and the second binding pins of the chip on film are pins that realizes electrical signal conduction of an interior of the chip on film and the first binding pins of the chip on film.

9. The automatic conversion method of the binding pins as claimed in claim 5, wherein generating the signal identifiers of the binding pins of the circuit board according to the signal identifiers of the first binding pins of the chip on film comprises:
merging the signal identifiers of the first binding pins of the chip on film which are adjacent and have same pin signals automatically through the electronic design automation program, and
redefining the merged signal identifiers to obtain signal identifiers of second binding pins of the chip on film sequentially; and
generating the signal identifiers of the binding pins of the circuit board according to the signal identifiers of the second binding pins of the chip on film.

10. The automatic conversion method of the binding pins as claimed in claim 2, wherein the plurality of pin serial numbers corresponding to one of the pin signals are not adjacent to each other.

11. An automatic conversion method of binding pins, comprising:
defining signal identifiers of binding pins of a display panel; and
recognizing the signal identifiers of the binding pins of the display panel automatically by an electronic design automation program, and generating and outputting signal identifiers of binding pins of a circuit board.

12. The automatic conversion method of the binding pins as claimed in claim 11, wherein the signal identifiers of the binding pins of the display panel comprise pin serial numbers and pin signals.

13. The automatic conversion method of the binding pins as claimed in claim 12, wherein the pin serial numbers of the binding pins of the display panel are Arabic numbers arranged in sequence, and
the pin signals of the binding pins of the display panel are electric signals received by the binding pins of the display panel.

14. The automatic conversion method of the binding pins as claimed in claim 12, wherein defining the signal identifiers of the binding pins of the display panel comprises:
defining the binding pins of the display panel manually, and identifying the binding pins of the display panel by two levels of the pin serial numbers and the pin signals,
wherein each of the pin serial numbers respectively corresponds to one of the pin signals.

15. The automatic conversion method of the binding pins as claimed in claim 11, wherein recognizing the signal identifiers of the binding pins of the display panel automatically by the electronic design automation program and generating and outputting the signal identifiers of the binding pins of the circuit board comprise:
recognizing the signal identifiers of the binding pins of the display panel automatically by the electronic design automation program;
generating signal identifiers of first binding pins of a chip on film according to the signal identifiers of the binding pins of the display panel;
generating the signal identifiers of the binding pins of the circuit board according to the signal identifiers of the first binding pins of the chip on film; and
outputting the signal identifiers of the binding pins of the circuit board.

16. The automatic conversion method of the binding pins as claimed in claim 15, wherein the first binding pins of the chip on film are pins bound to the binding pins of the display panel, and the first binding pins of the chip on film correspond to the binding pins of the display panel one-to-one.

17. The automatic conversion method of the binding pins as claimed in claim 15, wherein generating the signal identifiers of the binding pins of the circuit board according to the signal identifiers of the first binding pins of the chip on film comprises:
merging the signal identifiers of the first binding pins of the chip on film which are adjacent and have same pin signals automatically through the electronic design automation program, and
redefining the merged signal identifiers to obtain the signal identifiers of the binding pins of the circuit board sequentially.

18. The automatic conversion method of the binding pins as claimed in claim 17, wherein the binding pins of the circuit board are pins bound to second binding pins of the chip on film, the binding pins of the circuit board correspond to the second binding pins of the chip on film one-to-one, and the second binding pins of the chip on film are pins that realizes electrical signal conduction of an interior of the chip on film and the first binding pins of the chip on film.

19. The automatic conversion method of the binding pins as claimed in claim 15, wherein generating the signal identifiers of the binding pins of the circuit board according to the signal identifiers of the first binding pins of the chip on film comprises:
merging the signal identifiers of the first binding pins of the chip on film which are adjacent and have same pin signals automatically through the electronic design automation program, and
redefining the merged signal identifiers to obtain signal identifiers of second binding pins of the chip on film sequentially; and
generating the signal identifiers of the binding pins of the circuit board according to the signal identifiers of the second binding pins of the chip on film.

20. An automatic conversion system of binding pins, comprising:
a defining module configured to define signal identifiers of binding pins of a display panel; and
a recognition module configured to recognize the signal identifiers of the binding pins of the display panel automatically;
a conversion module configured to convert the signal identifiers of the binding pins of the display panel into signal identifiers of binding pins of a circuit board; and
an output module configured to output the signal identifiers of the binding pins of the circuit board.
